(19) United States
(12) Patent Application Publication
(10) Pub. No.: US 2005/0243902 A1
(43) Pub. Date: Nov. 3, 2005

(54) Vhf adapter for cable network

(76) Inventors: Jean-Luc Robert, Betton (FR); Jean-Yves Le Naour, Pace (FR); Charline Guguen, Rennes (FR)

Correspondence Address: THOMSON LICENSING INC., PATENT OPERATIONS, PO BOX 5312, PRINCETON, NJ, 08543-5312, US

(21) Appl. No.: 10/520,721

(22) PCT Filed: Jun. 25, 2003
(86) PCT No.: PCT/EP03/50260

§ 371 Date: Jan. 9, 2005

(30) Foreign Application Priority Data
Jul. 10, 2002 (FR) 0208939

(51) Int. Cl. H03K 11/00; H04L 25/60

(52) U.S. Cl. 375/214

(57) ABSTRACT

The invention relates to VHF adapters for cable networks of the ODU type. It consists in using two conversion chains, up and down, in which a very stable signal reference oscillator drives means of generating the VHF and IF local frequencies common to these two conversion chains. A very selective surface wave filter makes it possible to rject the frequency of the local oscillator at the level of the first intermediate frequency. It makes it possible to obtain a DOCSIS compatible millimeter MWS ODU whose frequency stability and spectral purity satisfy the constraints of the cable standard without undertaking spectral inversion of the signals transmitted and received.

The present invention concerns VHF adapters, commonly called ODUs (standing for “Outdoor Units”), intended more particularly for receiving by radio the signals originating from a base station fed from a cable network, so as to transmit these signals to an application terminal, especially a video or data terminal. This ODU unit is exterior to the application terminal.

Recent years have witnessed the emergence of point-multipoint distribution systems for a large number of millimetre frequency bands. The earliest studies related only to analogue broadcasting systems whereas nowadays it is digital systems offering interactive services that are in the forefront.

The term “Multimedia Wireless System: WMS” has been chosen to designate all systems which provide for convergence between the world of broadcasting and the world of telecommunications and which deliver broadband wireless access to the subscriber for multimedia services. These systems require a great deal of bandwidth and the 40 GHz (40.5-43.5 GHz) band has been designated in Europe for such systems.

It is recalled that RF transmission systems of point-multipoint type are known to the person skilled in the art by the initials MMDS (standing for Microwave Multipoint Distribution System), LMDS (standing for Local Multipoint Distribution System) and MVDS (standing for Multipoint Video Distribution System). These systems used for the broadcasting of programmes permit a return path to the subscriber terminals which allows the subscriber to interact with the programme received.

In Europe, it is planned to implement an LMDS type system which has 24 broadcasting channels (also called downlinks) having a bandwidth of 33 MHz, and 25 return channels (or uplinks) having a bandwidth of 2 MHz, these channels being situated between 40.5 and 42.5 GHz (for further details about the apportioning of these channels, the person skilled in the art may consult the MPT-1560-RA standard).

The system implemented must comply with the ETSI 301199 standard better known by the name LMDS DVB which among other things provides for an oscillator drift of plus or minus 200 kHz for the uplink, the drift being due mainly to climatic conditions. For further information about these systems, the person skilled in the art may refer for example to patent application WO 2002/33855.

The bandwidth allotted for this type of application has been increased and currently corresponds to the frequency band lying between 40.5 and 43.5 GHz as stated hereinabove. It is also planned to segment this band so as to apportion it between several operators.

The present invention pertains to the general framework of these transmission systems.

Specifically, one seeks to use a wireless communication system of the MWS or LMDS type to plug into an existing cable network, a video and/or data terminal which can normally be plugged directly into this network. To do this, the MWS system must be transparent in relation to the cable network and hence comply with the constraints set by the standard, of the DOCSIS type (standing for “Data Over Cable Service Interface Specification”) or EuroDOCSIS type for example, used in regard to this cable network.

These constraints are very severe for a terminal operating in the millimetre frequency bands used in MWS systems, typically 40.5-43.5 GHz, especially in terms of frequency stability and phase noise.

In order for a millimetre MWS ODU unit to meet the DOCSIS standard, it must comply with the following technical constraints:
Provide IF (standing for Intermediate Frequencies) accesses at 91 MHz/857 MHz for the down channels, and 5 MHz/65 MHz for the up channels;
satisfy the frequency stability and phase noise constraints of the cable standard, which are already severe in themselves on account of the high-order QAM type modulations used, at millimetre frequencies;
not perform spectral inversion of the signal transmitted or received.

The structure of a conventional MWS ODU unit is represented in FIG. 1. It uses between an antenna appliance 101 and an intermediate frequency (IF) output multiplexer 102 two conversion chains of known type making it possible to obtain the IF for down reception RX at 950/1950 MHz, and the IF for up transmission TX at 400/700 MHz. To do this, use is made of a local oscillator 103 of DRO type (dielectric resonator oscillator) common to the two conversion chains to go from the 40 GHz range to the 1000 MHz range, and a local oscillator LO1 104 of ordinary type on the up chain to obtain the desired frequency gap.

This structure is simple and cheap, but it does not make it possible to comply with the technical constraints cited above, or to obtain the various frequency plans of the DOCSIS standard with a single embodiment.

To comply with these constraints and obtain a multimode single version of the ODU with this architecture, it would be necessary to complicate the latter in such a way that it would lead to an unacceptable overhead cost.

To surmount these difficulties, the invention proposes a VHF adapter for cable network, of the type comprising a first down conversion chain and a second up conversion chain, principally characterized in that the first chain comprises a first mixer followed by a second mixer and the second chain a third mixer followed by a fourth and by a fifth mixer, and in that all the local frequencies necessary for these five mixers are obtained from a very stable single reference oscillator.

According to another characteristic, the single reference oscillator drives a harmonics generator inserted into a phase loop dielectric resonator oscillator using an SPD (Sample Phase Detector) system to obtain on the one hand after multiplication by two a first local frequency energizing the first and fifth mixers, and on the other hand with a very narrow filtering of a particular harmonic a second local frequency for energizing the second and the fourth mixers.

According to another characteristic, the single reference oscillator furthermore drives an agile frequency synthesizer controlled by a bus so as to obtain variable frequencies for energizing the fourth mixer; and in that a second very narrow filter is placed between the output of the third mixer and an input of the fourth mixer so that, the intermediate frequency for energizing the third mixer being a very low frequency pure frequency, the signal delivered by this third mixer can be filtered by the second very narrow filter which energetically rejects the second local frequency and the image-frequency signal.

Advantageously the first and second very narrow filters are surface wave filters.

According to another characteristic, the frequency plan of the various mixers makes it possible to obtain by simple switching of the frequencies of the harmonics generator and of the agile synthesizer and by a single change of the surface wave filters, four configurations for two distinct operators compatible with a cable network.

The subject of the invention is also a radio-frequency transmission system comprising at least one base station and at least one subscriber device, the base station using a single oscillator to perform a down conversion of signals to the frequency band transmitted by radio and possibly an up conversion of signals from the frequency band received by radio, the subscriber device comprising an interior unit and an exterior unit which are linked by a cable, principally characterized in that the exterior unit comprises a VHF adapter as defined above.

Other features and advantages of the invention will become clearly apparent in the following description, presented by way of nonlimiting example with regard to the appended figures which represent:

FIG. 1, the diagram of a known architecture of an ODU;

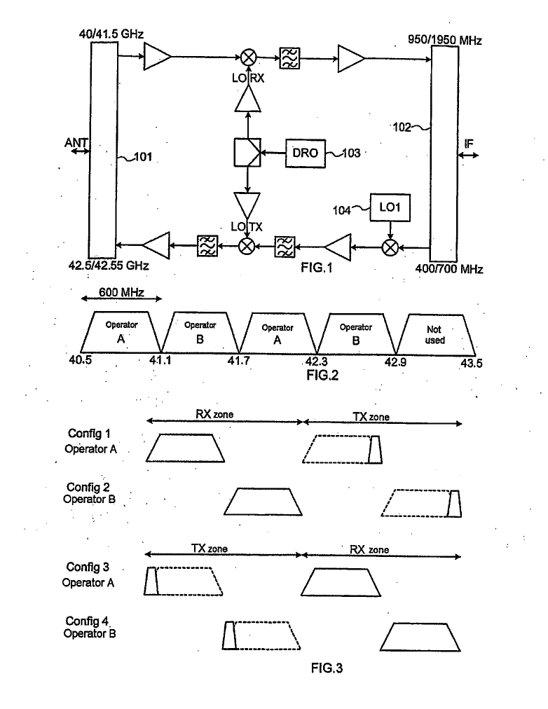

FIG. 2, the spectral apportioning of the frequencies for an MWS system at 40 GHz;

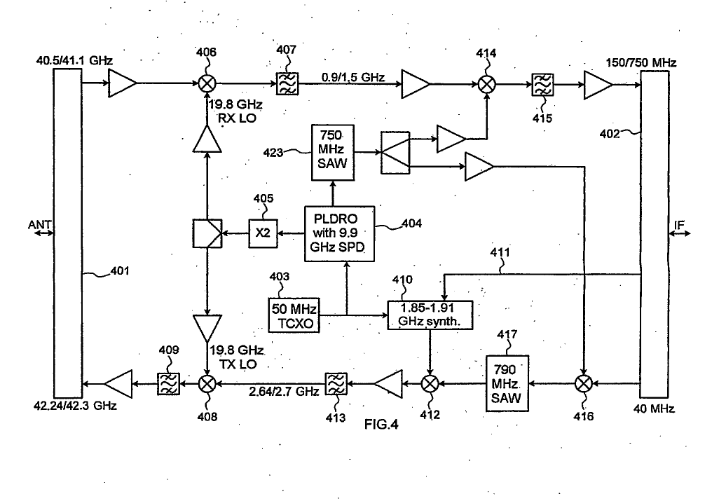

FIG. 3, the four possible configurations between two operators in the apportionment of FIG. 2;

FIG. 4, the diagram of an architecture of an ODU according to the invention;

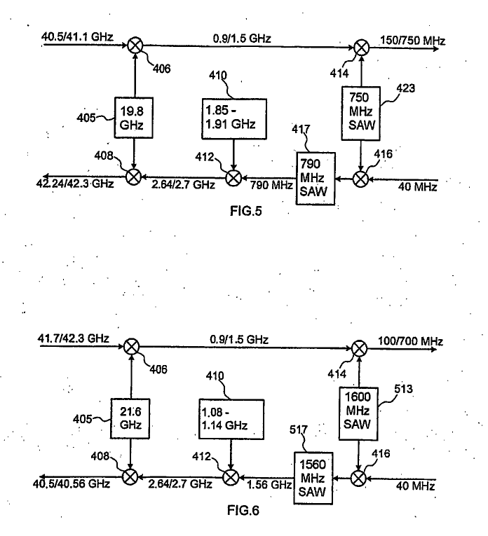

FIGS. 5 and 6, two simplified schematic diagrams corresponding to the two basic configurations contained in the four configurations of FIG. 3; and

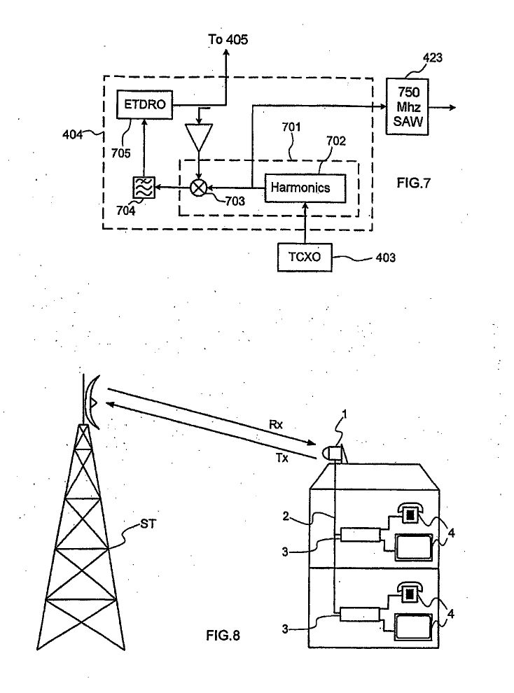

FIG. 7, an exemplary architecture of the means for generating the VHF and IF local frequencies;

FIG. 8, a distribution system using the invention.

A spectral apportioning, represented in FIG. 2, of the frequencies which is usable for a 40 GHz MWS system makes it possible to obtain for two operators, A and B, the four configurations represented in FIG. 3.

In the first two configurations, the down reception for the two operators is carried out at the bottom of the bands of the bottom zone A and the up transmission is carried out at the top of the bands of the top zone B.

The apportionment is reversed in the last two configurations.

The diagram of an architecture of an ODU unit according to the invention is represented in FIG. 4 with as an example, the numerical values of the frequencies in the case of configuration 1.

An antenna appliance 401 receives the VHF down frequencies 40.5 to 41.1 GHz and up frequencies 42.24 to 42.3 GHz.

Two conversion chains link this appliance 401 to a multiplexer 402 which delivers the intermediate frequencies, down lying between 150 and 750 MHz and up corresponding to a channel centred at 40 MHz.

The stability and purity of the local frequencies necessary for these conversion chains are ensured through the use of a single local oscillator 403 with 50 MHz TCXO type crystal to generate the reference frequency which drives all these frequencies.

This oscillator 403 firstly drives a harmonics generator 404 inserted into an oscillator of the phase loop dielectric resonator type (PLDRO) using an SPD (standing for “Sampling Phase Detector”) system.

This harmonics generator makes it possible to obtain firstly a local frequency at 9.9 GHz which is then multiplied by two in a multiplier 405 to obtain a frequency at 19800 MHz.

A mixer 406 followed by a filter 407 then makes it possible to obtain in the down chain the second infradyne product at 900/1500 MHz.

Likewise, a mixer 408 followed by a filter 409 makes it possible to obtain in the up chain the second supradyne product at 42.3/42.24 GHz.

The mixers 406 and 408 are VHF mixers performing a sub-harmonic conversion of order 2.

The oscillator 403 also drives an agile frequency synthesizer 410 controlled from the multiplexer 402 by a bus 411 so as to obtain variable frequencies between 1.85 and 1.91 GHz. These frequencies make it possible, with the aid of a mixer 412 and of a filter 413, to obtain the up frequencies 2.64/2.7 GHz applied to the mixer 408, from the first up IF with carrier frequency 790 MHz.

A filter 423 makes it possible to obtain from the harmonics generator 404 a local frequency of 750 MHz. This very narrow filter is of the surface wave type (SAW) so as to obtain a very pure frequency.

From this frequency, a mixer 414 and a filter 415 make it possible to obtain the final down IF at 150/750 MHz.

Likewise, a mixer 416 and a filter 417 make it possible from the up IF at the carrier frequency of 40 MHz to obtain the said carrier frequency at 790 MHz. This filter 417 is of the SAW type, hence very selective, so as to energetically reject the local frequency at 750 MHz. Referring again to FIG. 3, it is noted that for a given configuration where reception is performed in zone A and transmission in zone B, or vice versa, the terminal of the operator B differs from that of the operator A only through a simple frequency shift of 600 MHz of the harmonics generator 404, it being possible to perform this through a simple switching.

Likewise the spectral noninversion, which ensures spectral compatibility, is ensured by the spectral apportioning of the infradyne and supradyne mixers, as described hereinabove, by switching the frequencies of the generator 404 and of the synthesizer 410 and by changing two surface wave filters so as to comply with the frequency plans of the basic configurations 1 and 3; the move to configurations 2 and 4 is performed by simple shifting, as described hereinabove.

Represented in FIGS. 5 and 6 are the simplified schematics corresponding to these two basic configurations.

FIG. 5 relates to configuration 1, which corresponds to the numerical values of FIG. 4, and FIG. 6 corresponds to configuration 3. Clearly, all the elements are the same, with the exception of the SAW surface wave filters 423 and 417, which are replaced by surface wave filters 513 and 517 adjusted to different frequencies. These filters are very small items and may be disposed in the apparatus right from the outset, with simple means of switching for going from one to another in the event of a change of configuration. The change of frequency at the level of the doubler 405 is performed by simple adjustment at the level of the generator 404, and that at the level of the synthesizer 410 by a simple modification of the commands originating from the bus 411.

In an exemplary embodiment of the means for generating the VHF local frequency: LOVHF and IF local frequency: LOIF, represented in FIG. 7, the reference oscillator 403 energizes, in an SPD system 701, a harmonics generator 702. According to a variant embodiment (not represented), a high-frequency divider could be used to carry out this generation.

The signal output by this generator is applied to a mixer 703 which moreover receives the VHF output frequency of the assembly. The output signal from this mixer is filtered in a filter 704 whose output is applied to a voltage-controlled dielectric resonator oscillator 704 of the ETDRO (standing for Electrically Tuned Dielectric Resonator Oscillator) or VCDRO (standing for Voltage Controlled Dielectric Resonator Oscillator) type. The latter generates, with great spectral purity, the VHF local frequency. The looping back of the latter by way of the mixer 703 and of the filter 704 produces a phase loop which ensures frequency stability and spectral purity. The adjustment of the frequency is achieved by acting mechanically on the resonator so as to make it lock onto another harmonic of the harmonic generator 702. Finally, the filter 423, of SAW type, makes it possible to extract the intermediate frequency IF frequency from the output signal from the generator 702.

FIG. 8 illustrates a distribution network system serving as relay for a cable network. A base station ST furnished with a transmitter and possibly with a receiver, broadcasts information intended for a plurality of subscribers. On the subscriber side, the unit 1 exterior to the subscriber appliances is connected to a cable network 2. A subscriber can connect up to the cable network 2 with the aid of an interior unit 3 which serves as interface for one or more user apparatuses 4.

The exterior unit 1 comprises the antenna and the VHF adapter just described and which constitutes a means for transposing the signals received into a frequency band compatible with the cable network 2 and transposing signals to be transmitted to the base station ST. The interior unit 3 is for example a TV decoder or a modem intended for the cable network 2. The user apparatus 4 is for example a television, a telephone or a computer.

To summarize, the architecture according to the invention makes it possible to obtain a DOCSIS compatible millimetre MWS ODU whose frequency stability and phase purity satisfy the constraints of the cable standard without performing any spectral inversion of the signals transmitted and received.

To this end and as has been described, the architecture uses a very stable single reference oscillator which drives means for generating the VHF and IF local frequencies common to two conversion chains, up and down, very selective surface wave filters for rejecting the local frequency at the level of the first intermediate frequency, and a frequency synthesizer which is agile in the intermediate band in the up direction.

The ODU unit proposed allows compatibility of the radio link in the 40.5-43.5 GHz band with cable appliances satisfying the very widespread DOCSIS standard. This unit allows the operator to offer a low-cost interface between a cable network and a wireless link (for example of LMDS sub-network type).

Study of the frequency plans makes it possible to show that the use of low-cost surface-wave filters (SAW) from the telecommunications market (GSM or DCS) is possible.

This ODU unit also finds an application in respect of 28 GHZ LMDS systems.

1- VHF adapter for cable network, of the type comprising a first down conversion chain and a second up conversion chain, wherein the first chain comprises a first mixer followed by a second mixer and the second chain a third mixer followed by a fourth and by a fifth mixer, and wherein all the local frequencies necessary for these five mixers are obtained from a very stable single reference oscillator.

2- Adapter according to claim 1, wherein the single reference oscillator drives a harmonics generator inserted into a phase loop dielectric resonator oscillator using an SPD system to obtain on the one hand after multiplication by two a first local frequency energizing the first and fifth mixers, and on the other hand with a first very narrow filter a second local frequency for energizing the second and the third mixers

3- Adapter according to claim 2, wherein the single reference oscillator furthermore drives an agile frequency synthesizer controlled by a bus so as to obtain variable frequencies for energizing the fourth mixer; and wherein a second very narrow filter is placed between the output of the third mixer and an input of the fourth mixer so that, the intermediate frequency for energizing the third mixer being a very low frequency pure frequency, the signal delivered by this third mixer can be filtered by the second very narrow filter which energetically rejects the second local frequency and the image-frequency signal.

4- Adapter according to claim 3, wherein the first and second very narrow filters are surface wave filters.

5- Adapter according to claim 4, wherein the frequency plan of the first to fifth various mixers makes it possible to obtain by simple switching of the frequencies of the harmonics generator of the agile synthesizer and by a single change of the first and second surface wave filters, four configurations for two distinct operators compatible with a cable network.

6- Radio-frequency transmission system comprising at least one base station and at least one subscriber device, the base station using a single oscillator to perform a down conversion of signals to the frequency band transmitted by radio and possibly an up conversion of signals from the frequency band received by radio, the subscriber device comprises an interior unit and an exterior unit which are linked by a cable, wherein the exterior unit comprises a VHF adapter comprising a first down conversion chain and a second up conversion chain, wherein the first chain comprises a first mixer followed by a second mixer and the second chain a third mixer followed by a fourth and by a fifth mixer, and wherein all the local frequencies necessary for these five mixers are obtained from a very stable single reference oscillator.

7- Radio frequency transmission system according to claim 6, wherein the single reference oscillator of the adapter drives a harmonics generator inserted into a phase loop dielectric resonator oscillator using an SPD system to obtain on the one hand after multiplication by two a first local frequency energizing the first and fifth mixers, and on the other hand with a first very narrow filter a second local frequency for energizing the second and the third mixers.

8- Radio frequency transmission system according to claim 7, wherein the single reference oscillator furthermore drives an agile frequency synthesizer controlled by a bus so as to obtain variable frequencies for energizing the fourth mixer; and wherein a second very narrow filter is placed between the output of the third mixer and an input of the fourth mixer so that, the intermediate frequency for energizing the third mixer being a very low frequency pure frequency, the signal delivered by this third mixer can be filtered by the second very narrow filter which energetically rejects the second local frequency and the image-frequency signal.

9- Radio frequency transmission system according to claim 8, wherein the frequency plan of the first to fifth various mixers makes it possible to obtain a simple switching of the frequencies of the harmonics generator and of the agile synthesizer and by a single change of the first and second surface wave filters, four configurations for two distinct operators compatible with a cable network.
